(19) United States
(12) Patent Application Publication
(10) Pub. No.: US 2006/0163650 A1
(43) Pub. Date: Jul. 27, 2006

(54) Power semiconductor device with endless gate trenches

(76) Inventor: Ling Ma, Torrance, CA (US)

Correspondence Address: OSTROLENK FABER GERB & SOFFEN, 1180 AVENUE OF THE AMERICAS, NEW YORK, NY, 100368403, US

(21) Appl. No.: 11/338,215

(22) Filed: Jan. 24, 2006

Related U.S. Application Data
(60) Provisional application No. 60/647,728, filed on Jan. 27, 2005.

(51) Int. Cl. H01L 29/94

(52) U.S. Cl. 257/330

(57) ABSTRACT

A power semiconductor device which includes endless gate trenches.

### RELATED APPLICATION

This application is based on and claims benefit of U.S. Provisional Application No. 60/647,728, filed on Jan. 27, 2005, entitled The Tipless Trench Design, to which a claim of priority is hereby made and the disclosure of which is incorporated by reference.

### BACKGROUND OF THE INVENTION

Referring to FIG. 1, a power semiconductor device according to the prior art includes a plurality of spaced gate trenches 3, each having a gate insulation body (typically composed of silicon dioxide) lining the sidewalls thereof, and a gate electrode 7 disposed therein. Gate trenches 3 in a prior art device have terminal ends 9. In a known design, a gate bus 11 (which has been rendered transparent for better illustration) is disposed over at least one end 9 of each gate trench 3 in electrical contact with a gate electrode 7 therein.

It is a common commercial practice to rate a power semiconductor device prior to shipping the same to an end user. To perform a voltage breakdown rating, the device is subjected to, for example, a certain screening voltage.

It has been observed that gate insulation 5 at end 9 has been a source of premature breakdown. Therefore, screening voltages have been set low to avoid the premature breakdown during rating and qualification. As a result, it has been difficult to isolate devices with trench defects and the like during the screening and qualification process.

It is, therefore, desirable to reduce or eliminate insulation premature gate insulation breakdown in order to improve the rating and qualification process.

### SUMMARY OF THE INVENTION

A power semiconductor device according to the present invention includes a drift region of a first conductivity, a base region of a second conductivity over the drift region, a plurality of endless trenches extending through the base region to the drift region, a gate insulation layer formed in each endless trench adjacent at least the base region, and an endless gate electrode residing in each endless trench.

It has been found that by using endless trenches the location of the breakdown of the gate insulation is moved to the active region. As a result, it is possible to screen the devices with higher voltages. The higher screening voltages are effective in weeding out devices with defective trenches or the like. Thus, the rating and qualification process is enhanced.

In the preferred embodiment of the present invention, each endless trench includes two spaced parallel trenches and two curved connecting trenches connecting the two parallel trenches to form an endless trench. A gate bus is preferably disposed over at least a portion of one of the connecting trenches and electrically connected to the gate electrode. In the preferred embodiment, an endless trench is spaced from another endless trench by an active region, and each endless trench includes an active region residing within an interior region thereof.

Other features and advantages of the present invention will become apparent from the following description of the invention which refers to the accompanying drawings.

### BRIEF DESCRIPTION OF THE DRAWINGS

FIG. 1 shows a top plan view of a portion of a power semiconductor device according to the prior art.

FIG. 2 shows a top plan view of a portion of a power semiconductor device according to the preferred embodiment of the present invention.

FIG. 3 shows a cross-sectional view of a device according to the present invention along line 3-3 in FIG. 2, viewed in the direction of the arrows.

FIG. 4 shows a micrograph of a prior art device after failure illustrating that the location of the failure of the gate insulation is at the end of the gate trenches.

FIG. 5 shows a micrograph of a device according to the present invention illustrating that the location of the failure of the gate insulation is in the active region.

### DETAILED DESCRIPTION OF THE PREFERRED EMBODIMENT

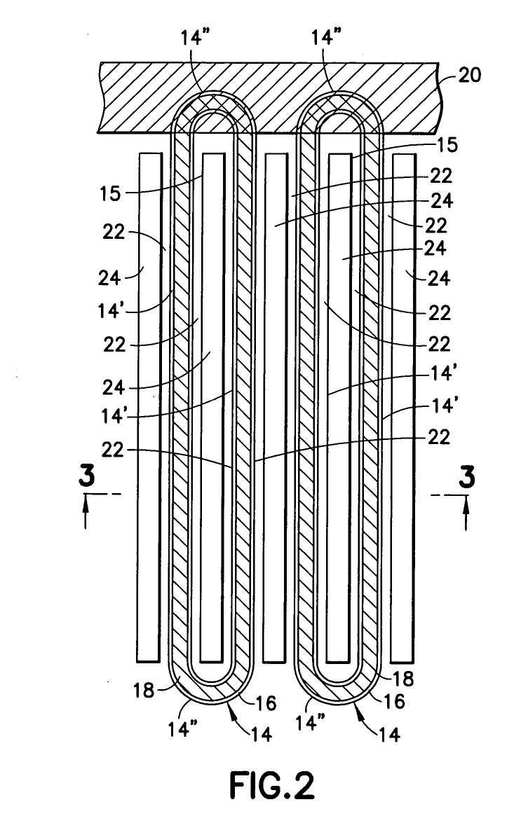

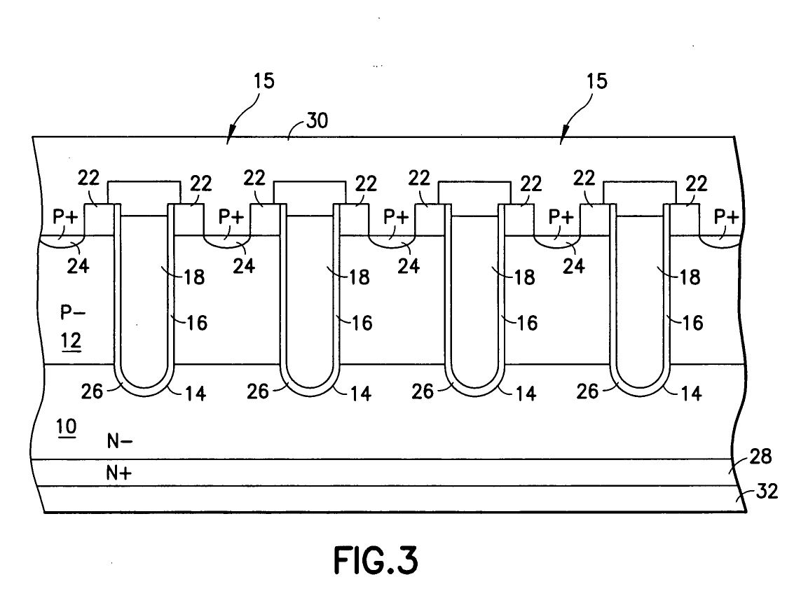

Referring to FIGS. 2 and 3, a power semiconductor device according to an embodiment of the present invention includes drift region 10 of a first conductivity (e.g. N-type), base region 12 of a second conductivity (e.g. P-type) over drift region 10, a plurality of endless trenches 14 extending through base region 12 to drift region 10, a gate insulation layer 16 formed in each endless trench 14 adjacent at least base region 12, and an endless gate electrode 18 residing in each endless trench 14.

According to the present invention, each endless trench 14 includes two spaced parallel trenches 14′, and two opposing connecting trenches 14″ connecting parallel trenches 14′.

A device according to the present invention further includes conductive regions 22 of the first conductivity over body region 12 adjacent each parallel trench 14′ of each endless trench 14. Furthermore, a high conductivity region 24 of the second conductivity type but of lower resistivity than body region 12 (e.g. P+) is formed in body region 12 between two opposing conductive regions 22.

Conductive regions 22 are part of what is commonly referred to as an active region. As seen in the Figures, in the preferred embodiment each endless trench 14 is spaced from another endless trench 14 by an active region, and includes an active region within an interior region 15 thereof. Furthermore, in the preferred embodiment of the present invention, connecting trenches 14″ are curved.

In the preferred embodiment, gate bus 20 (which has been rendered partially transparent for better illustration) is disposed over at least a portion of one connecting trench 14″ of each endless trench 14 and electrically connected to gate electrode 18 disposed therein. Furthermore, preferably, each endless trench 14 has a curved bottom, and thick insulation body 26 (thicker than gate insulation 16) over the curved bottom. Preferably, drift region 10 is an epitaxially formed semiconductor body residing over a substrate 28 of the same semiconductor material and the same conductivity.

A device according to the present invention further includes first power electrode 30 ohmically connected to conductive regions 22 and high conductivity regions 24, and second power electrode 32 electrically connected to substrate 28.

A device according to the present invention may be a power MOSFET, in which case, conductive regions 22 are source regions, first power electrode 30 is the source electrode, and second power electrode 32 is the drain electrode. Alternatively, a device according to the present invention may be an IGBT, in which case, conductive regions 22 may be emitter regions, first power electrode 30 may be the emitter electrode and second power electrode may be the collector electrode.

In the preferred embodiment, drift region 10 is an epitaxially formed silicon that is formed over a silicon substrate, endless gate electrodes 18 and gate bus 20 are formed with conductive polysilicon, and gate insulation 16 and insulation bodies 26 are formed with silicon dioxide. First and second power electrodes 30, 32 may be formed with any suitable metal, for example, aluminum or aluminum silicon.

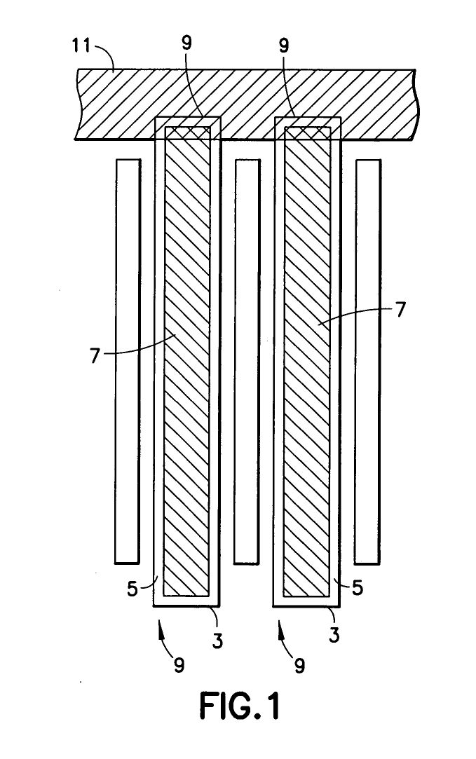

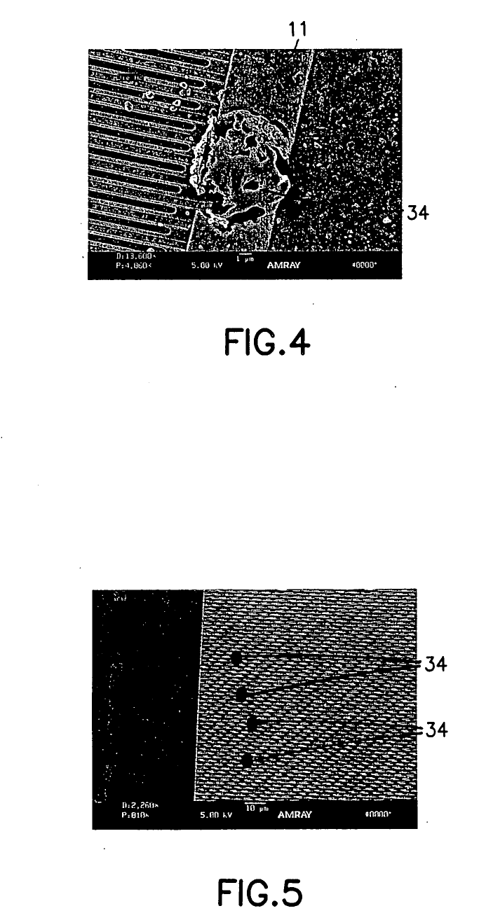

Referring next to FIG. 4, in a device according to the prior art (FIG. 1) breakdown location 34 of gate oxide 5 is observed at end 9 of gate trenches 3 below gate bus 11.

On the other hand, as seen in FIG. 5, in a device according to the present invention, breakdown location 34 of the gate oxide has been observed inside the active area of the device away from the connecting trenches 14′ and gate bus 20.

In tests, devices having endless trenches according to the present invention did not show any Igss related failures. On the other hand, devices according to the prior art in a control group had five Igss related failures. Further data regarding the enhanced performance of a device according to the present invention can be found in U.S. Provisional Application No. 60/647,728, filed on Jan. 27, 2005, entitled The Tipless Trench Design, the disclosure of which is incorporated by reference.

With the improvement in the breakdown voltage of the gate oxide in a device according to the present invention, it is possible to screen the parts with higher voltages. The higher screening voltages are effective in weeding out devices with defective trenches. As a result the rating and qualification process is enhanced.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A power semiconductor device comprising:
a drift region of a first conductivity;
a base region of a second conductivity over said drift region;
a plurality of endless trenches extending through said base region to said drift region;
a gate insulation layer formed in each endless trench adjacent said base region; and
a gate electrode residing in each endless trench.

2. The power semiconductor device of claim 1, wherein each said endless trench includes two spaced parallel trenches and two connecting trenches connecting said two parallel trenches to form an endless trench.

3. The power semiconductor device of claim 2, wherein said connecting trenches are curved.

4. The power semiconductor device of claim 2, further comprising a gate bus disposed over at least a portion of one of said connecting trenches and electrically connected to said gate electrode.

5. The power semiconductor device of claim 1, wherein said gate electrode is comprised of conductive polysilicon.

6. The power semiconductor device of claim 1, wherein said gate insulation is comprised of silicon dioxide.

7. The power semiconductor device of claim 1, wherein each said endless trench includes a curved bottom portion.

8. The power semiconductor device of claim 1, further comprising an insulation body disposed at the bottom of each endless trench, said insulation body being thicker than said gate insulation.

9. The power semiconductor device of claim 1, further comprising conductive regions of said first conductivity over said body region and adjacent said each endless trench.

10. The power semiconductor device of claim 1, wherein said drift region is disposed over a substrate.

11. The power semiconductor device of claim 10, wherein said substrate is comprised of silicon.

12. The power semiconductor device of claim 1, wherein said power semiconductor device is a MOSFET.

13. The power semiconductor device of claim 1, wherein said power semiconductor device is an IGBT.

14. A power semiconductor device comprising:
a plurality of spaced endless gate trenches each including two opposing and spaced trenches connected to one another by connecting trenches to form an endless gate trench;
a gate insulation liner lining at least the walls of said endless trenches;
an endless gate electrode disposed within each endless trench; and
a voltage supply bus electrically connected to each of said endless gate electrodes.

15. The power semiconductor device of claim 14, wherein each endless gate trench is spaced from another endless gate trench by an active region and each endless gate trench includes an active region residing within an interior region thereof.

16. The power semiconductor device of claim 14, wherein said connecting trenches are curved.

17. The power semiconductor device of claim 14, wherein each active region includes a conductive region of first conductivity adjacent a respective gate trench and a high conductivity of second conductivity disposed between said conductive regions of said first conductivity.

18. The power semiconductor device of claim 16, further comprising a gate bus residing over at least a portion of one of said connecting portions and electrically connected to said gate electrode disposed within said endless gate trench.

19. The power semiconductor device of claim 14, wherein each endless gate trench includes a curved bottom.
